(19) United States
(12) Patent Application Publication
(10) Pub. No.: US 2015/0096715 A1
(43) Pub. Date: Apr. 9, 2015

(54) HEAT DISSIPATION SYSTEM

(71) Applicant: HON HAI PRECISION INDUSTRY CO., LTD., New Taipei (TW)

(72) Inventor: TAI-WEI LIN, New Taipei (TW)

(73) Assignee: HON HAI PRECISION INDUSTRY CO., LTD., New Taipei (TW)

(21) Appl. No.: 14/067,972

(22) Filed: Oct. 31, 2013

(30) Foreign Application Priority Data
Oct. 8, 2013 (TW) 102136301

(51) Int. Cl. H05K 7/20; F28F 27/02

(52) U.S. Cl. CPC H05K 7/20836; H05K 7/20781; F28F 27/02
USPC 165/11.1; 165/287

(57) ABSTRACT

A heat dissipation system for a number of cabinets mounted in a container includes a first heat dissipation apparatus, a second heat dissipation apparatus including a condenser, an inlet pipe assembly connected to the cabinets, an outlet pipe assembly connected to the cabinets, a connecting pipe connected between the inlet pipe assembly and the outlet pipe assembly, a extension pipe connected between the connecting pipe and the inlet pipe assembly, a first valve connected to the connecting pipe and located between the first dissipation apparatus and the second dissipation apparatus, a second valve connected to the extension pipe, a number of temperature sensors installed in the cabinets, and a controller electrically coupled to the temperature sensors, the first valve, the second valve, and the condenser. The controller controls the first valve, the second valve, and the condenser to turn on or off according to temperature sensed by the temperature sensors.

### BACKGROUND

1. Technical Field

The present disclosure relates to a heat dissipation system for a container data center.

2. Description of Related Art

A container data center includes a plurality of servers to store large amounts of data. The servers generate a considerable amount of heat, and the internal temperature of the container data center may rise due to the heat, which may affect performance of the servers. Therefore, air-conditioners are employed by the container data center to cool the servers. However, when only a small number of the servers of the container data center are operating, it will not be necessary to have all the air-conditioners working, in order to save energy. Therefore, a new heat dissipation system which can adjust the number of the air-conditioners to operate is needed for a container data center.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a schematic view of an embodiment of a heat dissipation system.

FIG. 2 is a block diagram of the heat dissipation system of FIG. 1.

FIG. 3 is similar to FIG. 1, but shows the heat dissipation system in a first state of use.

FIG. 4 is similar to FIG. 1, but shows the heat dissipation system in a second state of use.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

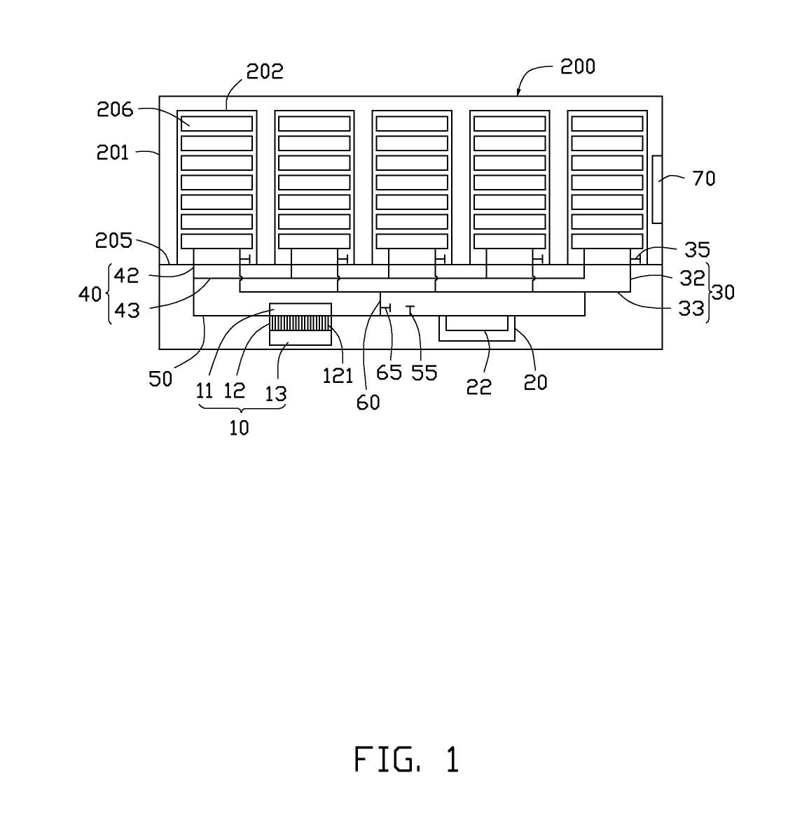

FIG. 1 shows an embodiment of a heat dissipation system for dissipating a plurality of cabinets 202 mounted in a container data center 200. The container data center 200 includes a container 201 and a supporting plate 205 installed in the container 201. The cabinets 202 are supported on the supporting plate 205. Each cabinet 202 includes a plurality of servers 206. The heat dissipation system includes a first heat dissipation apparatus 10, a second heat dissipation apparatus 20, an inlet pipe assembly 30, an outlet pipe assembly 40, a connecting pipe 50, an extension pipe 60, a first valve 55, a second valve 65, and a controller 70.

The first heat dissipation apparatus 10 and the second heat dissipation apparatus 20 are located below the supporting plate 205. The first heat dissipation apparatus 10 includes a water tank 11, a heat sink 12 attached to the water tank 11, and a fan 13 installed to the heat sink 12. The heat sink 12 includes a plurality of fins 121. The second heat dissipation apparatus 20 includes a condenser 22.

The inlet pipe assembly 30 includes a main pipe 33, a plurality of branch pipes 32 connected between the main pipe 33 and the cabinets 202, and a plurality of flow control valves 35 installed to the branch pipes 32. The flow control valves 35 are used for controlling the flow of the cooling liquid flowing to the corresponding cabinets 202.

The outlet pipe assembly 40 includes a main pipe 43 and a plurality of branch pipes 42 connected between the main pipe 43 and the cabinets 202.

The first heat dissipation apparatus 10 and the second heat dissipation apparatus 20 are connected in series by the connecting pipe 50, and two opposite ends of the connecting pipe 50 are connected between the main pipe 33 of the inlet pipe assembly 30 and the main pipe 43 of the outlet pipe assembly 40. The connecting pipe 50 extends through the water tank 11 and the condenser 22. The first valve 55 is installed to the connecting pipe 50, and located between the first heat dissipation apparatus 10 and the second heat dissipation apparatus 20.

An end of the extension pipe 60 is connected to a point of the connecting pipe 50 between the first heat dissipation apparatus 10 and the first valve 55, and an opposite end of the extension pipe 60 is connected to the main pipe 33 of the inlet pipe assembly 30. The second valve 65 is installed to the extension pipe 60.

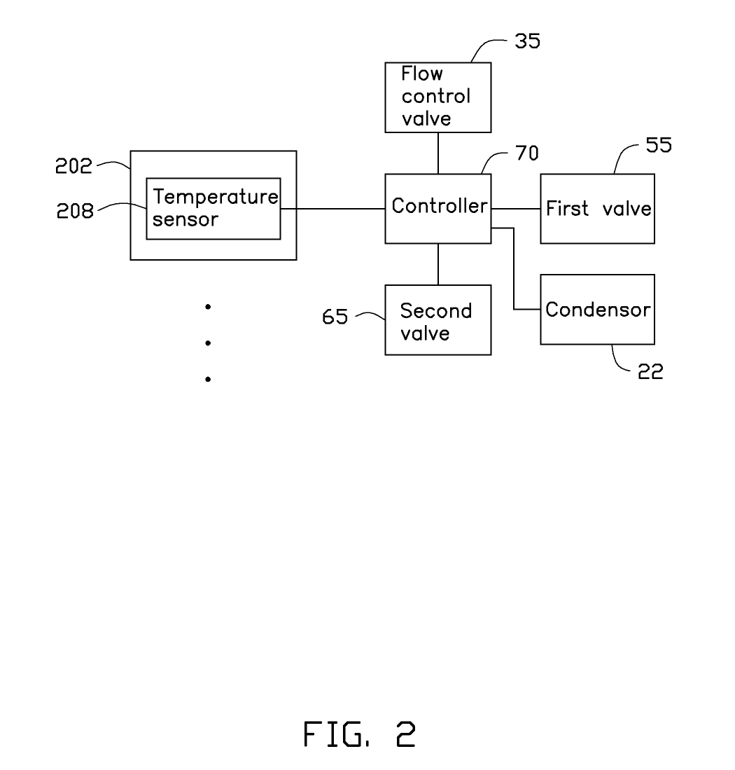

FIG. 2 is a block diagram of the heat dissipation system. Each cabinet 202 includes a temperature sensor 208 electrically coupled to the controller 70. The flow control valves 35, the first valve 55, the second valve 65, and the condenser 22 are electrically coupled to the controller 70. According to a temperature sensed by the temperature sensor 208, the controller 70 can control the flow control valves 35 to turn on or turn off, to control the flow flowing through the first valve 55 the second valve 65, and the condenser 22.

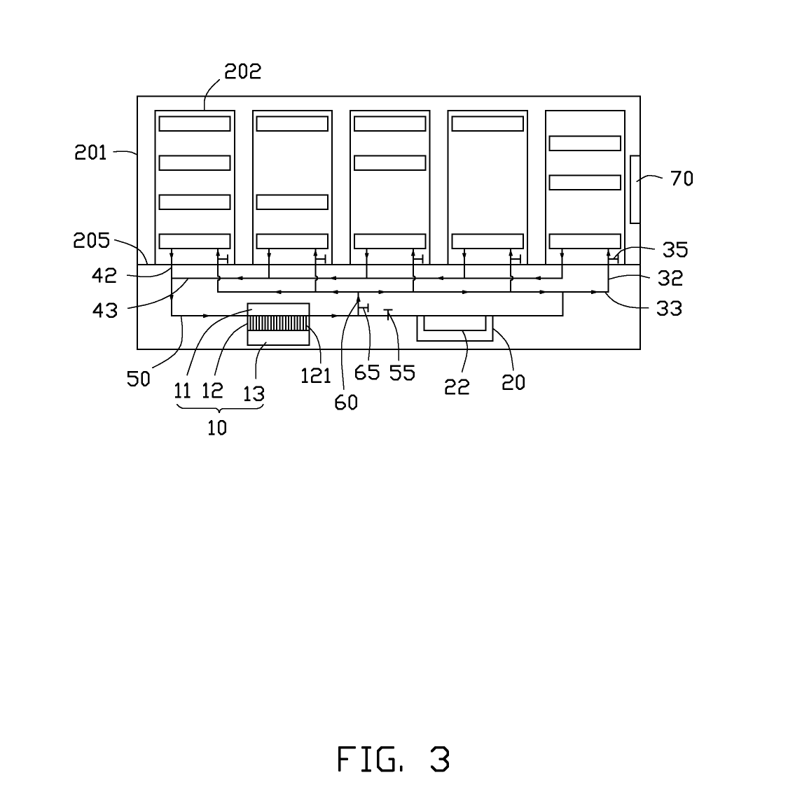

FIG. 3 shows the heat dissipation system in a first state of use. The servers 206 of the cabinets 202 operate to generate a lot of heat. The temperature sensor 208 of each cabinet 202 outputs a first signal to the controller 70 when the temperature of all the cabinet 202 is less than a predetermined value, to allow the controller 70 to control the first valve 55 to turn off and control the second valve 65 to turn on. The cooling liquid of the water tank 11 flows through the connecting pipe 50, the extension pipe 60, the main pipe 33, and the branch pipes 32 of the inlet pipe assembly 30, to enter the cabinets 202. The heat of the cabinets 202 is transferred to the cooling liquid. Thus, the cooling liquid is heated. The heated cooling liquid flows back into the water tank 11 through the branch pipes 42, the main pipe 43 of the outlet pipe assembly 40, and the connecting pipe 50. The heat of the heated cooling liquid in the water tank 11 is transferred to the fins 121, and the fan 13 dissipates the heat from the fins 121. The controller 70 further controls the flow control valves 35 according to the temperature sensed by the temperature sensors 208 of the cabinets 202.

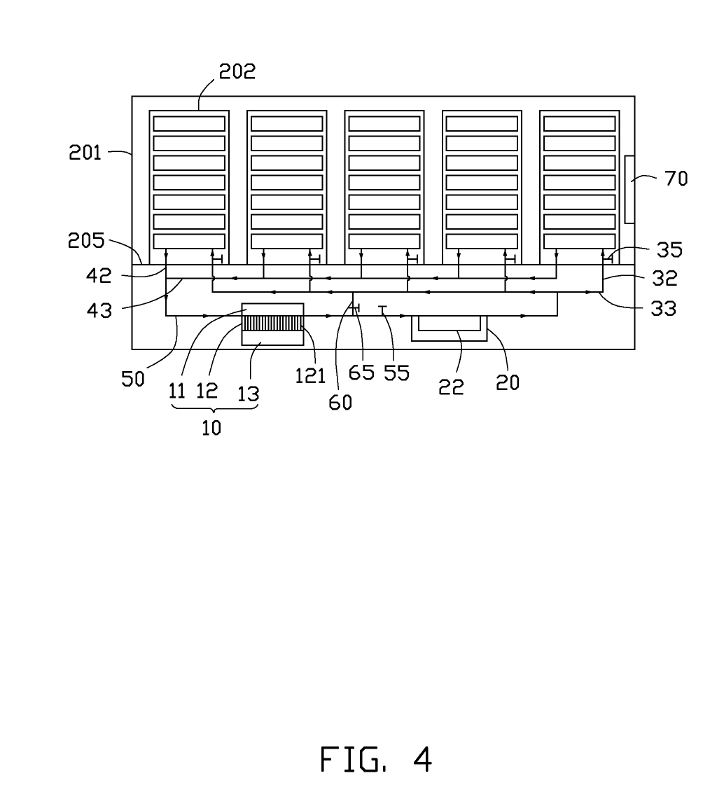

FIG. 4 shows the heat dissipation system in a second state of use. The temperature sensor 208 outputs a second signal to the controller 70 when the temperature of any one of the cabinets 202 is greater than the predetermined value, to allow the controller 70 to control the first valve 55 to turn on and control the second valve 65 to turn off. The cooling liquid of the water tank 11 flows into the second heat dissipation apparatus 20 through the connecting pipe 50. The condenser 22 of the second heat dissipation apparatus 20 further cools the cooling liquid. The cooling liquid from the water tank 11 flows through the condenser 22 to be further cooled, then flows through the inlet pipe assembly 30, to enter the cabinets 202. The heat of the cabinets 202 is transferred to the cooling liquid. The heated cooling liquid flows back into the water tank 11 through the outlet pipe assembly 40 and the connecting pipe 50. The controller 70 further controls the flow control valves 35 according to the temperature sensed by the temperature sensors 208 of the cabinets 202.

It is to be understood, that even though numerous characteristics and advantages of the embodiment have been set forth in the foregoing description, together with details of the structure and function of the embodiment, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A heat dissipation system for cooling a plurality of cabinets mounted in a container data center, the heat dissipation system comprising:
a connecting pipe comprising a first end and a second end;
an inlet pipe assembly connected between the first end of the connecting pipe and each of the plurality of cabinets;
an outlet pipe assembly connected between the second end of the connecting pipe and the each of the plurality of cabinets;
a first heat dissipation apparatus comprising a water tank connected to the connecting pipe and receiving cooling liquid, the first heat dissipation apparatus adjacent to the second end of the connecting pipe;
a second heat dissipation apparatus comprising a condenser connected to the connecting pipe and adjacent to the first end of the connecting pipe;
a first valve connected to the connecting pipe, and located between the first heat dissipation apparatus and the second heat dissipation apparatus;
an extension pipe comprising a first end connected to the inlet pipe assembly, and a second end connected to a point of the connecting pipe between the first dissipation apparatus and the first valve;
a second valve connected to the extension pipe;
a plurality of temperature sensors installed in the plurality of cabinets; and
a controller electrically coupled to the plurality of temperature sensors, the first valve, the second valve, and the condenser;
wherein the controller controls the first valve, the second valve, and the condenser to turn on or off, according to temperature sensed by the plurality of temperature sensors.

2. The heat dissipation system of claim 1, wherein each of the plurality of temperature sensors outputs a first signal to the controller when the temperature of all the cabinets is less than a predetermined value, to allow the controller to control the first valve to turn off and control the second valve to turn on, cooling liquid from the first heat dissipation apparatus flows through the extension pipe and the inlet pipe assembly, to enter the plurality of cabinets, heat of the plurality of cabinets is transferred to the cooling liquid, the heated cooling liquid flows back into the first dissipation apparatus through the outlet pipe assembly and the connecting pipe.

3. The heat dissipation system of claim 2, wherein the temperature sensor outputs a second signal to the controller when the temperature of any one of the plurality of cabinets is greater than the predetermined value, to allow the controller to control the first valve to turn on and control the second valve to turn off, the cooling liquid from the first heat dissipation apparatus flows to the second heat dissipation apparatus through the connecting pipe, the condenser of the second dissipation apparatus further cools the cooling liquid, the cooling liquid then flows through the inlet pipe assembly to enter the plurality of cabinets, the heat of the plurality of cabinets is transferred to the cooling liquid, the heated cooling liquid flows back into the first heat dissipation apparatus through the connecting pipe.

4. The heat dissipation system of claim 1, wherein the inlet pipe assembly comprises a first main pipe, and a plurality of first branch pipes connected between the corresponding cabinets and the first main pipe, the outlet pipe assembly comprises a second main pipe, and a plurality of second branch pipes connected between the corresponding cabinets and the second main pipe, the first end of the connecting pipe is connected to the first main pipe, and the second end of the connecting pipe is connected to the second main pipe, the extension pipe is connected between the first main pipe and the connecting pipe.

5. The heat dissipation system of claim 4, wherein the inlet pipe assembly further comprises a plurality of flow control valves connected to the plurality of first branch pipes, the plurality of flow control valves is electrically coupled to the controller, the controller controls the plurality of flow control valves to turn on or off according to temperature sensed by the corresponding temperature sensors.

6. The heat dissipation system of claim 1, wherein the first dissipation apparatus comprises a water tank connected to the connecting pipe.

7. The heat dissipation system of claim 6, wherein the first dissipation apparatus further comprises a heat sink attached to the water tank and a fan installed to the heat sink.

8. The heat dissipation system of claim 7, wherein the heat sink comprises a plurality of fins.
